(19) United States
(12) Patent Application Publication
(10) Pub. No.: US 2009/0004581 A1
(43) Pub. Date: Jan. 1, 2009

(54) Exposure apparatus, exposure method and optical proximity correction method

(76) Inventors: Kazuya Fukuhara, Tokyo (JP); Tatsuhiko Higashiki, Fujisawa-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/907,191

(22) Filed: Oct. 10, 2007

(30) Foreign Application Priority Data
Oct. 11, 2006 (JP) 2006-278069

(51) Int. Cl. G03C 5/00; G03F 7/00; G03B 27/72

(52) U.S. Cl. 430/30; 355/71; 430/311

(57) ABSTRACT

There is disclosed an exposure apparatus which includes an illumination optical system including a light source which emits illumination light, a mask stage which holds a photomask having a mask pattern thereon to be illuminated with the illumination light, and a light intensity distribution filter arranged on a plane, which plane is positioned in the illumination optical system and is optically in relation of Fourier transform to the mask pattern, the light intensity distribution filter configured to vary a light intensity distribution of the illumination light in a cross section of a bundle of the illumination light.

### CROSS-REFERENCE TO RELATED APPLICATIONS

This application is based upon and claims the benefit of priority from prior Japanese Patent Application No. 2006-278069, filed Oct. 11, 2006, the entire contents of which are incorporated herein by reference.

### BACKGROUND OF THE INVENTION

1. Field of the Invention

The present invention relates to an exposure technology, and more particularly to an exposure apparatus, an exposure method and an optical proximity correction method.

2. Description of the Related Art

In a recent situation where the miniaturization of the semiconductor device has been progressing, there is a strong demand of improving the performance of the exposure apparatus for manufacturing semiconductor devices. There has been proposed a method in which a filter is placed on a pupil plane of a projection optical system of an exposure apparatus, whereby an intensity of the 0th-order diffracted light is attenuated to increase a contrast of the projection image of the mask pattern (for example, Jpn. Pat. Appln. KOKAI Publication No. 6-61122). However, the proposal has the following problems. When the filter is placed on the pupil plane of the projection optical system, the filter absorbs the exposure light and is deformed so that an aberration occurs in the lens to disturb the focus characteristics. The approach of only attenuating the intensity of the 0th-order diffracted light fails to correct the optical proximity effect (OPE), which differs depending on the pitch of the mask pattern.

### BRIEF SUMMARY OF THE INVENTION

According to a first aspect of the present invention, there is provided an exposure apparatus comprising:

an illumination optical system including a light source which emits illumination light;

a mask stage which holds a photomask having a mask pattern thereon to be illuminated with the illumination light; and

a light intensity distribution filter arranged on a plane, which plane is positioned in the illumination optical system and is optically in relation of Fourier transform to the mask pattern, the light intensity distribution filter configured to vary a light intensity distribution of the illumination light in a cross section of a bundle of the illumination light.

According to a second aspect of the present invention, there is provided an exposure method comprising:

emitting illumination light from a light source of a illumination optical system;

varying a light intensity distribution of the illumination light in a cross section of a bundle of the illumination light by using a light intensity distribution filter placed in an optical path of the illumination light in the illumination optical system; and

illuminating a mask pattern positioned on a plane optically in relation of Fourier transform to the light intensity distribution filter with the illumination light.

According to a third aspect of the present invention, there is provided an optical proximity correction method comprising:

illuminating a mask pattern including a plurality of diffraction patterns having different periods with illumination light generated from a light source;

measuring sizes of projection images of the plurality of diffraction patterns formed by illumination of the illumination light; and

varying, when the sizes of the projection images measured are each different from target values, a light intensity distribution in a cross section of a bundle of the illumination light on a plane which is between the mask pattern and the light source and is optically in relation of Fourier transform to the mask pattern, to correct the sizes of the projection images to be close to the target values.

### BRIEF DESCRIPTION OF THE SEVERAL VIEWS OF THE DRAWING

FIG. 1 is a diagram showing a scheme of an exposure apparatus according to an embodiment of the present invention;

FIG. 2 is a top view showing a lighting stop according to the embodiment of the present invention;

FIG. 3A is a top view showing the lighting stop according to the embodiment of the present invention and FIG. 3B is a graph showing a light distribution of illumination light having passed through the lighting stop of FIG. 3A;

FIG. 4 is a top view showing a photomask according to the embodiment of the present invention;

FIG. 5 is a perspective view showing a light intensity distribution filter according to the embodiment of the present invention;

FIG. 6 is a top view showing the light intensity distribution filter according to the embodiment of the present invention;

FIG. 7 is an enlarged top view showing a part of the light intensity distribution filter according to the embodiment of the present invention;

FIG. 8 is a cross-sectional view taken on line VIII-VIII in FIG. 7, the view also showing a part of the light intensity distribution filter according to the embodiment of the present invention;

FIG. 9 is an enlarged top view showing a part of the light intensity distribution filter according to the embodiment of the present invention;

FIG. 10 is a cross-sectional view taken on line X-X in FIG. 9, the view also showing a part of the light intensity distribution filter according to the embodiment of the present invention;

FIG. 11A is a top view showing the light intensity distribution filter according to the embodiment of the present invention, and FIG. 11B is a graph showing a light transmittance distribution of the light intensity distribution filter of FIG. 11A;

FIG. 12A is a top view showing a lighting stop according to the embodiment of the present invention, and FIG. 12B is a graph showing a light intensity distribution of light having passed through the light intensity distribution filter of FIG. 11A;

FIG. 13 is a graph showing a relationship between the line widths of projection images and the pitches of the same when no light intensity distribution filter is used;

FIG. 14 is a graph showing a relationship between the line widths of projection images and the pitches of the same when a light intensity distribution filter is used, according to the embodiment of the invention;

FIG. 15A is a top view showing the light intensity distribution filter according to the embodiment of the present invention, and FIG. 15B is a graph showing a light transmittance distribution of the light intensity distribution filter of FIG. 15A;

FIG. 16 is a flowchart showing a method for correcting the optical proximity effect according to the embodiment of the present invention;

FIG. 17 is a flowchart showing a method of manufacturing a semiconductor device according to the embodiment of the present invention;

FIG. 18 is a diagram showing a configuration of an exposure apparatus according to another embodiment of the present invention;

FIG. 19 is a top view showing a light intensity distribution filter according to a further embodiment of the present invention;

FIG. 20 is a top view showing a light intensity distribution filter according to a further embodiment of the present invention; and

FIG. 21 is a top view showing a revolver for the light intensity distribution filter, according to a further embodiment of the present invention.

### DETAILED DESCRIPTION OF THE INVENTION

Embodiments of the present invention will be described with reference to the accompanying drawings. Throughout the drawings, like reference symbols designate like or equivalent part and portions.

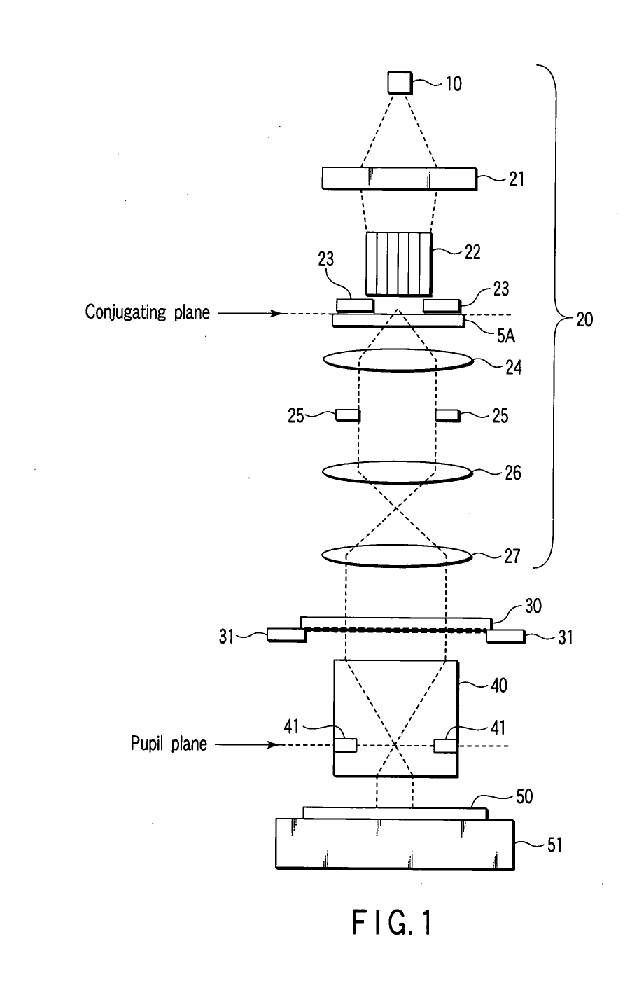

Referring to FIG. 1, there is schematically illustrated an exposure apparatus which is an embodiment of the present invention. As shown, the exposure apparatus is provided with an illumination optical system 20 including a light source 10 for emitting illumination light, e.g., argon fluoride (ArF) laser light, a mask stage 31 for holding a photomask 30 having a mask pattern to be illuminated with light, located under the illumination optical system 20, a projection optical system 40 located under the mask stage 31, and a wafer stage 51 for holding a wafer 50 to be illuminated with light, located under the projection optical system 40. A light intensity distribution filter 5A for varying a distribution of light intensities in the cross section of the bundle of the illumination light is arranged on a plane, which plane is positioned in an optical path of the illumination light located between the light source 10 in the illumination optical system 20 and the photomask 30 and is optically in a relation of Fourier transform to the mask pattern.

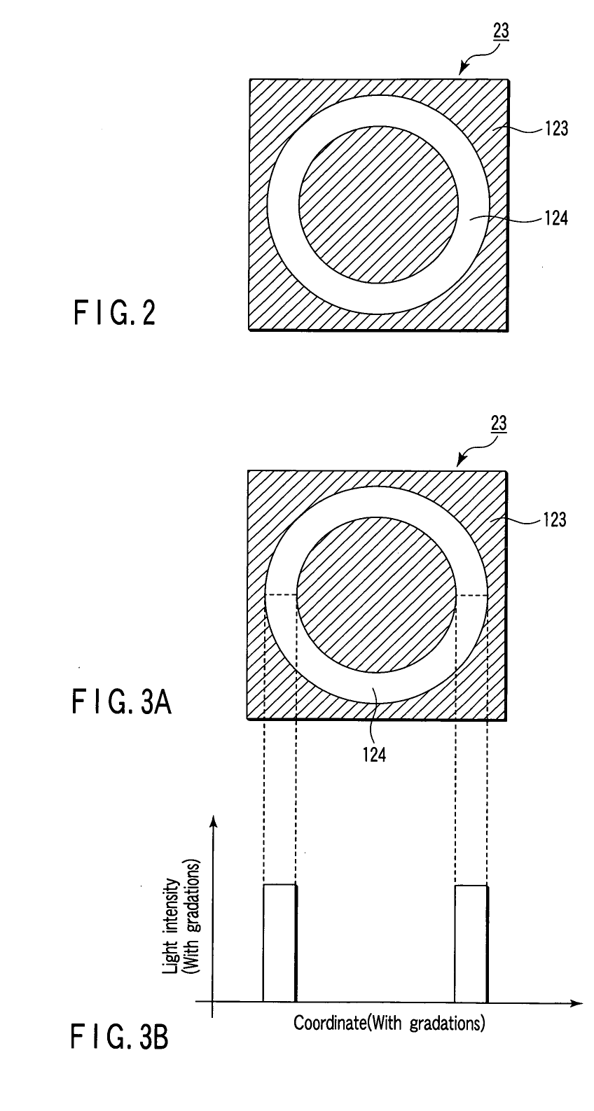

In the illumination optical system 20, a lens system 21 located under the light source 10 condenses illumination light. A fly-eye lens 22 is located under the lens system 21. The fly-eye lens 22 uniformizes a distribution of light intensities in the cross section of the bundle of the illumination light. A lighting stop 23 is located under the fly-eye lens 22. The lighting stop 23 defines the diameter of the bundle of the illumination light. The lighting stop 23, as shown in FIG. 2, includes a diaphragm light-shielding part 123, which is provided with a ring-like aperture 124. The illumination light passes through only the aperture 124. Therefore, with the use of the lighting stop 23, the annular illumination is formed. Accordingly, as shown in FIGS. 3A and 3B, the light intensity on a plane vertical to the optical axis of the illumination light having passed through the lighting stop 23 is 0 in an area shielded by the diaphragm light-shielding part 123. Assuming that a numerical aperture of the illumination optical system 20 is NA_{L} and the numerical aperture of the projection optical system 40 is Nap, a coherence ratio σ within the annular illumination, mathematically expressed by equation (1), is 0.76, for example, and the coherence ratio σ outside the annular illumination is 0.95, for example. The position where the lighting stop 23 is located is in a secondary light source plane (illumination pupil) of a secondary light source including the lens system 21 and the fly-eye lens 22 shown in FIG. 1. The illumination pupil has a finite area.

σ=NA_{L}/NAp (1)

A lens 24 for collimating the illumination light is located under the lighting stop 23. An exposure area stop 25 for defining an illumination area of the illumination light on the photomask 30 is located under the lens 24. A lens 26 for condensing the illumination light is located under the exposure area stop 25. The focal point position of the lens 26 optically conjugates with a position where the lighting stop 23 is located. A lens 27 for collimating the illumination light again is located under the lens 26.

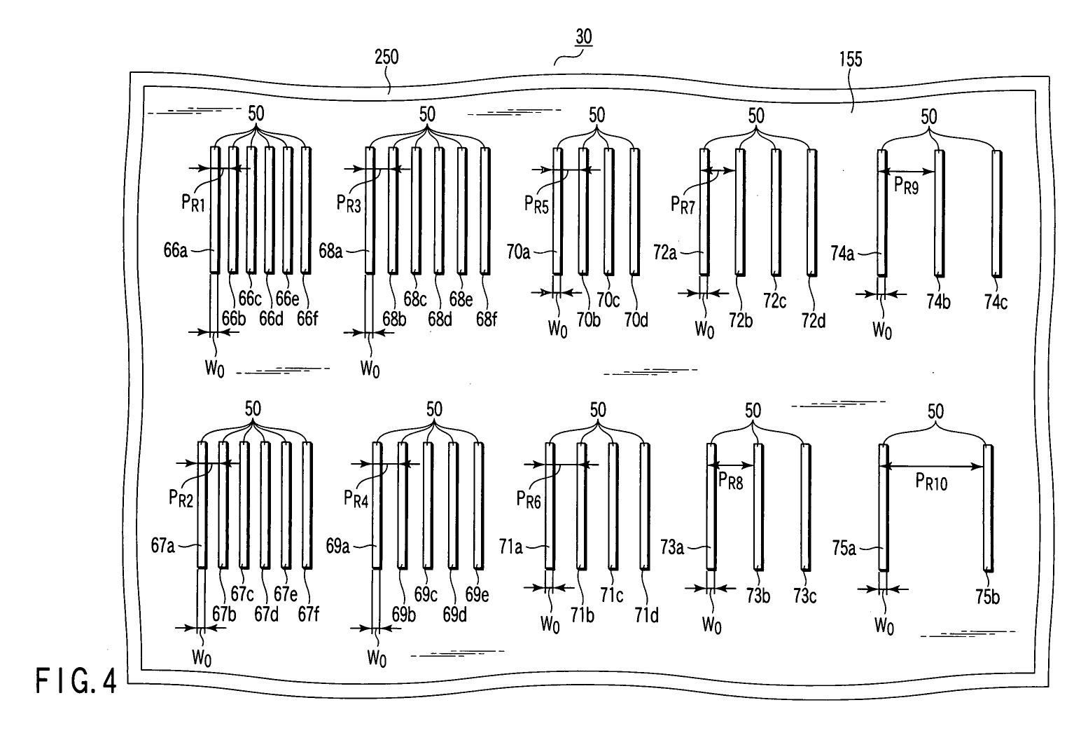

The mask stage 31 for holding the photomask 30 is located under the illumination optical system 20 including the lens system 21, the fly-eye lens 22, and the lenses 24, 26 and 27. The position where the photomask 30 is placed on the mask stage 31 optically conjugates with the position where the exposure area stop 25 is placed. The photomask 30, as shown in FIG. 4, for example, includes a mask substrate 250 transparent to illumination light and a light attenuation film 155 located on the bottom surface of the mask substrate 250. The light attenuation film 155 is opaque to the illumination light or attenuates the intensity of illumination light. The light attenuation film 155 is provided with a plurality of first diffraction patterns 66a, 66b, 66c, 66d, 66e and 66f, a plurality of second diffraction patterns 67a, 67b, 67c, 67d, 67e and 67f, a plurality of third diffraction patterns 68a, 68b, 68c, 68d, 68e and 68f, a plurality of fourth diffraction patterns 69a, 69b, 69c, 69d and 69e, a plurality of fifth diffraction patterns 70a, 70b, 70c and 70d, a plurality of sixth diffraction patterns 71a, 71b, 71c, and 71d, a plurality of seventh diffraction patterns 72a, 72b, 72c, and 72d, a plurality of eighth diffraction patterns 73a, 73b and 73c, a plurality of ninth diffraction patterns 74a, 74b, and 74c , and a plurality of tenth diffraction patterns 75a and 75b. Silica glass or the like may be used as the material of the mask substrate 250. Chromium (Cr), molybdenum silicide (MoSi) or the like may be used as the material of the light attenuation film 155. The first diffraction patterns 66a to 66f, the second diffraction patterns 67a to 67f, the third diffraction patterns 68a to 68f, the fourth diffraction patterns 69a to 69e, the fifth diffraction patterns 70a to 70d, the sixth diffraction patterns 71a to 71d, the seventh diffraction patterns 72a to 72d, the eighth diffraction patterns 73a to 73c, the ninth diffraction patterns 74a to 74c, and the tenth diffraction patterns 75a and 75b provided on the light attenuation film 155 are all strip-like openings each having a line width W_{O} and congruent to one another. The mask substrate 250 is exposed at each of the openings and the illumination light passes through each of the openings. The first to tenth diffraction patterns 66a to 75b form a mask pattern of the photomask 30.

The first diffraction patterns 66a to 66f are formed in the light attenuation film 155 at first reticle pitches PR1. The second diffraction patterns 67a to 67f are formed in the light attenuation film 155 at second reticle pitches PR2, which are larger than the first reticle pitches PR1. The third diffraction patterns 68a to 68f are formed in the light attenuation film 155 at third reticle pitches PR3, which are larger than the second reticle pitches PR2. The fourth diffraction patterns 69a to 69e are formed in the light attenuation film 155 at fourth reticle pitches PR4, which are larger than the third reticle pitches PR3. The fifth diffraction patterns 70a to 70d are formed in the light attenuation film 155 at fifth reticle pitches PR5, which are larger than the fourth reticle pitches PR4. The sixth diffraction patterns 71a to 71d are formed in the light attenuation film 155 at sixth reticle pitches PR6, which are larger than the fifth reticle pitches PR5. The seventh diffraction patterns 72a to 72d are formed in the light attenuation film 155 at seventh reticle pitches PR7, which are larger than the sixth reticle pitches PR6. The eighth diffraction patterns 73a to 73c are formed in the light attenuation film 155 at eighth reticle pitches PR8, which are larger than the seventh reticle pitches PR7. The ninth diffraction patterns 74a to 74c are formed in the light attenuation film 155 at ninth reticle pitches PR9, which are larger than the eighth reticle pitches PR8. The tenth diffraction patterns 75a and 75b are formed in the light attenuation film 155 at tenth reticle pitches PR10, which are larger than the ninth reticle pitches PR9.

The projection optical system 40 of which the numerical aperture NAp is 0.93, for example, is located under the mask stage 31 shown in FIG. 1. The illumination light is diffracted on the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b, shown in FIG. 4, which are formed in the photomask 30, and the diffracted light rays interfere with one another on the pupil plane of the projection optical system 40 shown in FIG. 1. The Fourier images of the first diffraction patterns 66a to 66f, the Fourier images of the second diffraction patterns 67a to 67f, the Fourier images of the third diffraction patterns 68a to 68f, the Fourier images of the fourth diffraction patterns 69a to 69e, the Fourier images of the fifth diffraction patterns 70a to 70d, the Fourier images of the sixth diffraction patterns 71a to 71d, the Fourier images of the seventh diffraction patterns 72a to 72d, the Fourier images of the eighth diffraction patterns 73a to 73c, the Fourier images of the ninth diffraction patterns 74a to 74c, and the Fourier images of the tenth diffraction patterns 75a and 75b are formed in the pupil plane of the projection optical system 40.

The pupil plane in the projection optical system 40 shown in FIG. 1 optically conjugates with a plane on which the focal point of the lens 26 is set. An aperture stop 41 is located in the pupil plane of the projection optical system 40. The wafer stage 51 for holding the wafer 50, which is illuminated with the illumination light, is located under the projection optical system 40. The wafer 50 is made of silicon (Si) or the like. The position at which the photomask 30 is located optically conjugates with the position at which the wafer 50 is located. The projection images of the first diffraction patterns 66a to 66f, the projection images of second diffraction patterns 67a to 67f, the projection images of third diffraction patterns 68a to 68f, the projection images of fourth diffraction patterns 69a to 69e, the projection images of fifth diffraction patterns 70a to 70d, the projection images of sixth diffraction patterns 71a to 71d, the projection images of seventh diffraction patterns 72a to 72d, the projection images of eighth diffraction patterns 73a to 73c, the projection images of ninth diffraction patterns 74a to 74c, and the projection images of the tenth diffraction patterns 75a and 75b, as shown in FIG. 4, are formed on the wafer 50. The design value of the line width of each of the projection images on the wafer 50, of the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b is 65 nm, for example.

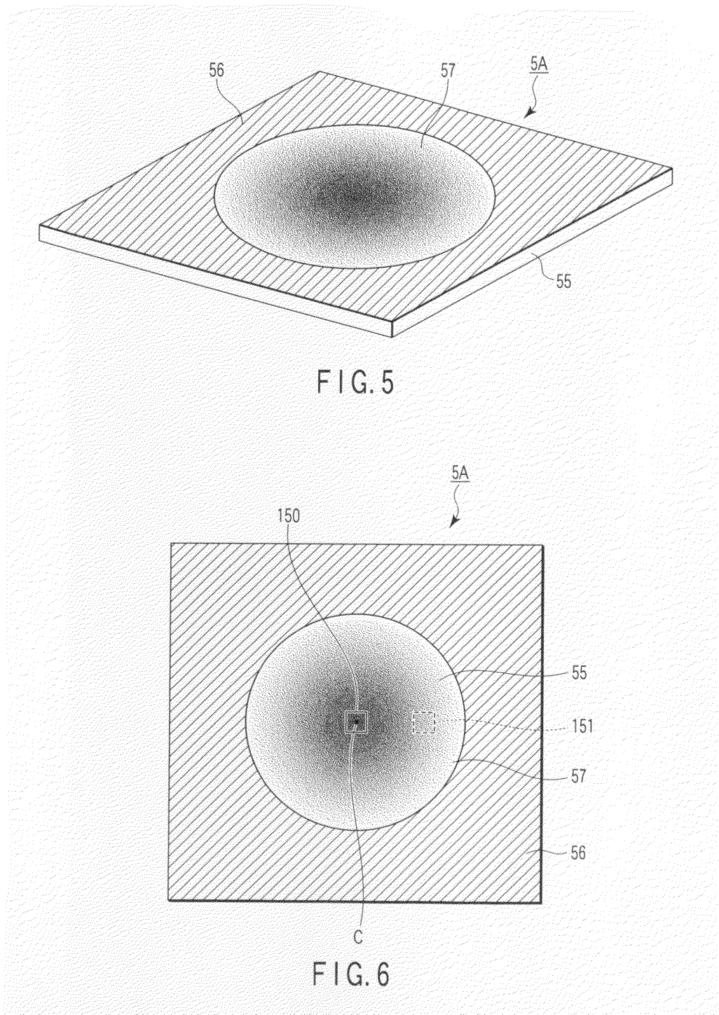

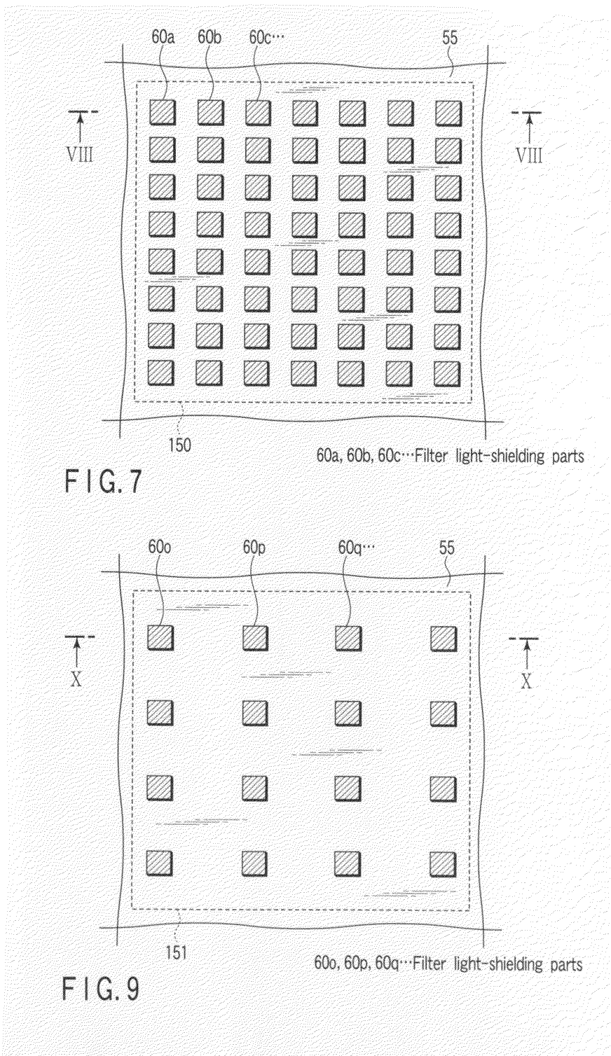

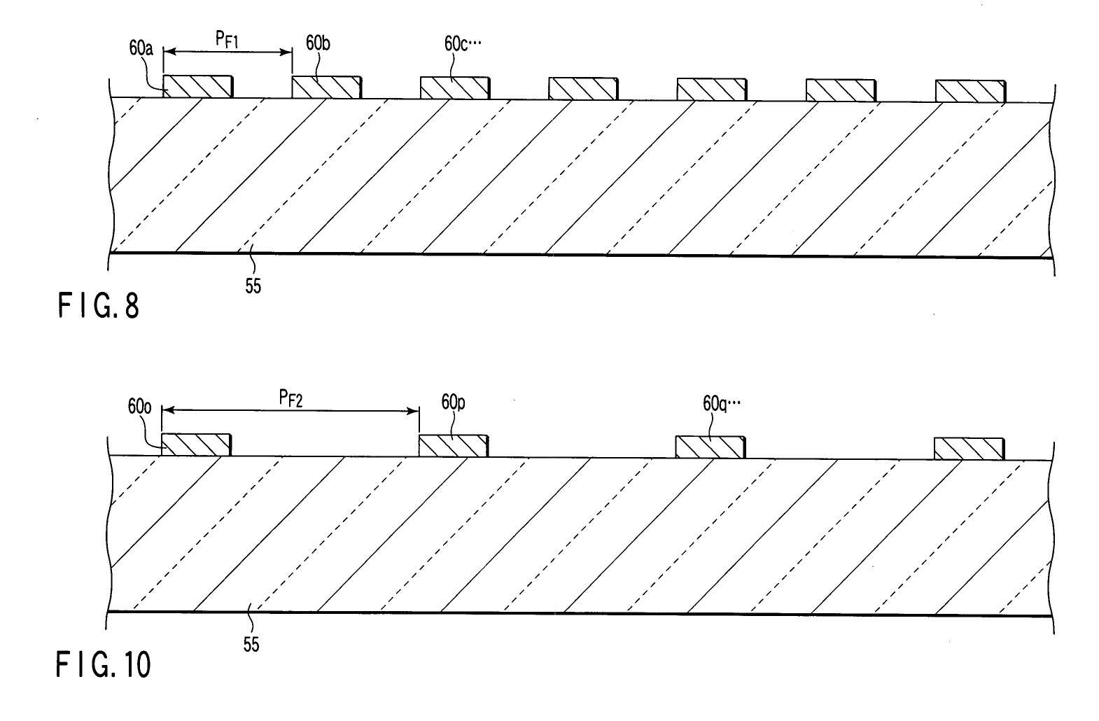

The light intensity distribution filter 5A, which is disposed in the illumination optical system 20 shown in FIG. 1, includes a filter substrate 55 and a light-shielding film 56 located on the filter substrate 55 and provided with a circular aperture 57, as shown in the perspective view of FIG. 5. The light intensity distribution filter 5A is located on a plane optically in a relation of Fourier transform to the mask pattern. The filter substrate 55 is made from dissolved silica or the like and transparent to the illumination light. The light-shielding film 56 is made of chromium (Cr) or the like, and opaque to the illumination light to shut off the illumination light. The filter substrate 55 is partially exposed through the aperture 57 and the exposed part of the filter substrate allows the illumination light to pass therethrough. The light intensity distribution filter 5A is orthogonal to the optical axis of the illumination optical system 20 of the exposure apparatus shown in FIG. 1 at the center C of the aperture 57 shown in FIG. 6. As shown in FIG. 7 showing an enlarged partial top view and FIG. 8 showing a VIII-VIII cross section in FIG. 7, a plurality of light-shielding parts 60a, 60b, 60c, . . . , which are made of chromium (Cr) or the like and opaque to the illumination light, are arrayed at filter pitch PF1 on the filter substrate 55 in an area 150 of the aperture 57, shown in FIG. 6, near the center C thereof. The filter pitch PF1 is of such a size as to prevent the illumination light from being diffracted at the light-shielding parts 60a, 60b, 60c, . . . , and is 10 times the wavelength of the illumination light or longer, or shorter than the wavelength. As shown in FIG. 9 showing an enlarged partial view and FIG. 10 showing an X-X cross section in FIG. 9, a plurality of light-shielding parts 60o, 60p, 60q, . . . made of chromium (Cr) or the like are arrayed on the filter substrate 55 at filter pitch PF2 on the filter substrate 55 in an area 151 of the aperture 57, shown in FIG. 6, near the peripheral portion thereof. The filter pitch PF2 is larger than the filter pitch PF1.

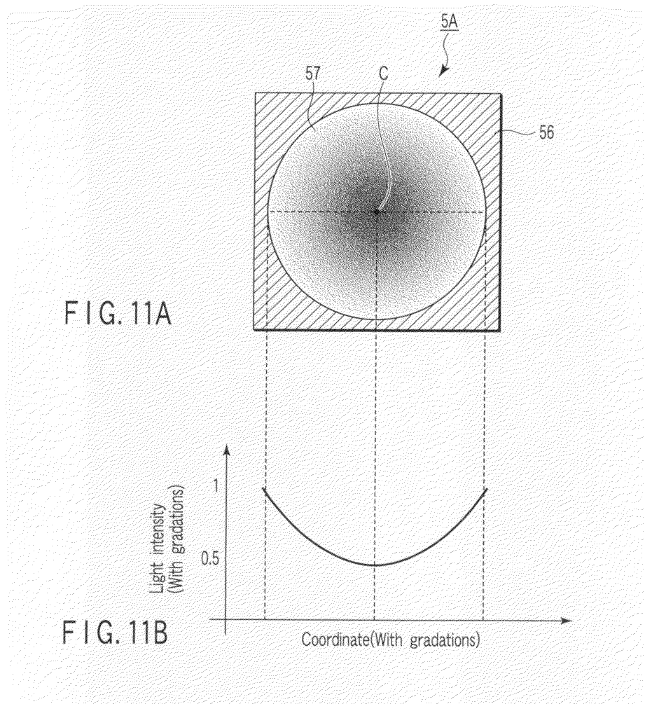

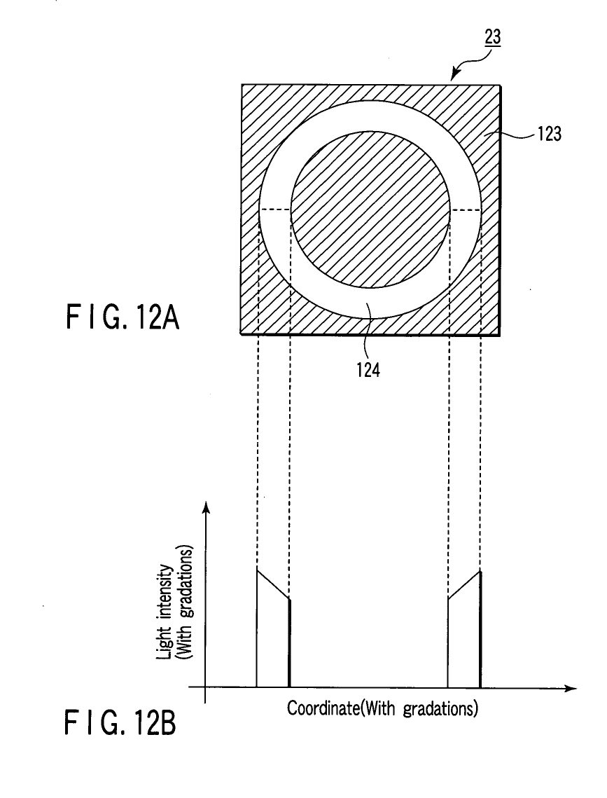

In the aperture 57 of the light intensity distribution filter 5A shown in FIG. 5, the light-shielding parts 60a, 60b, 60c, . . . shown in FIGS. 7 and 8 and the light-shielding parts 60o, 60p, 60q, . . . shown in FIGS. 9 and 10 are coaxially arrayed on the filter substrate 55 from the center C of the aperture 57 toward the periphery thereof. The pitch of the light-shielding parts arrayed in the aperture 57 of the light intensity distribution filter 5A increase from the center C of the aperture 57 toward the periphery thereof. Accordingly, the light transmittance is not uniform over the aperture 57 of the light intensity distribution filter 5A shown in FIG. 5. As shown in FIGS. 11A and 11B, the light transmittance is low in an area of the aperture 57 near the center C thereof, and increases toward the periphery of the aperture 57. In other words, the light intensity distribution filter 5A has a transmittance distribution expressed by a quadratic curve, which descends toward the center C when viewed in the radial direction. Accordingly, as shown in FIGS. 12A and 12B, the intensity of the illumination light in the inner region of the annular illumination created by the lighting stop 23 is lower than that in the circumferential region. The light intensity distribution filter 5A is located on a plane, which plane is positioned in the illumination optical system 20 and is optically in a relation of Fourier transform to the plane of the photomask 30 shown in FIG. 4 on which the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b are arranged. Actually, however, it is tolerable that the light intensity distribution filter 5A is located at a position which is displaced about 1 to 2 mm from the plane that is in relation of Fourier transform.

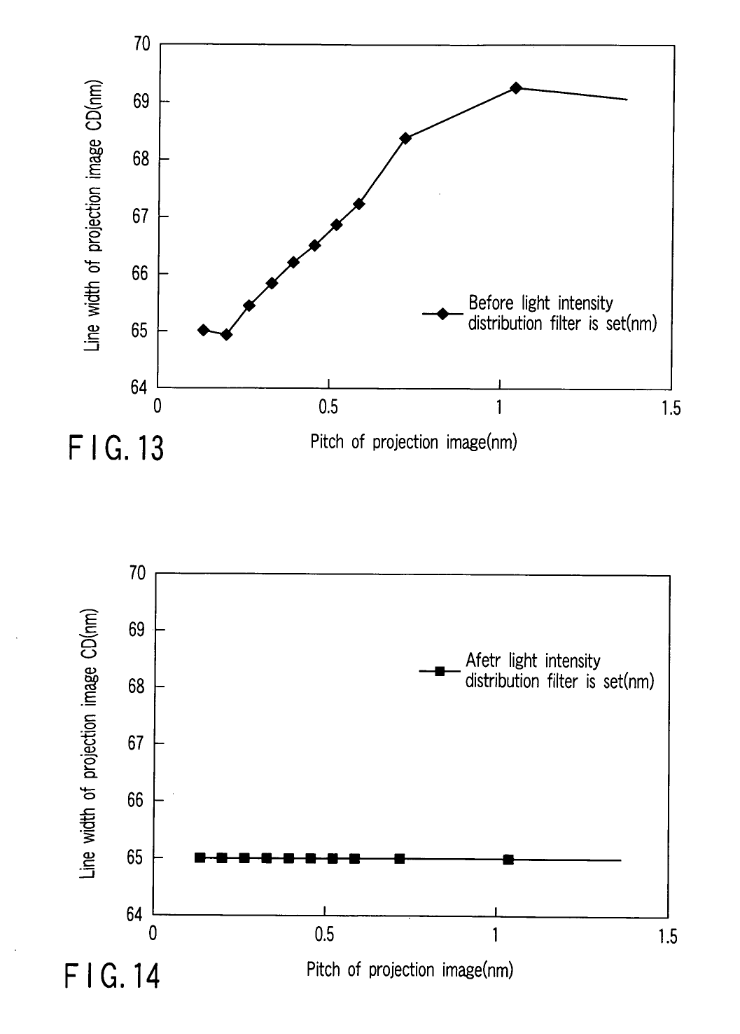

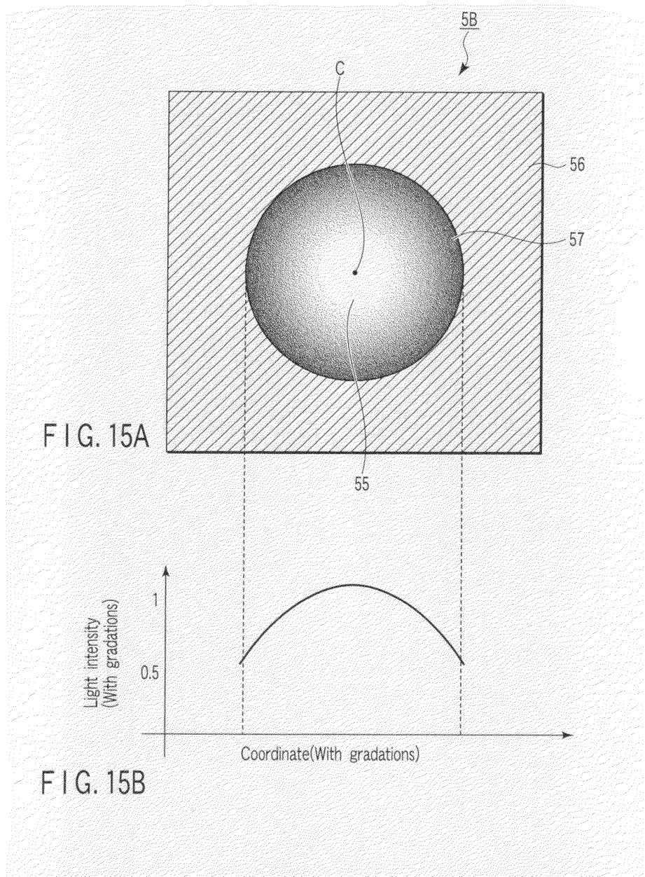

Referring to FIG. 13, there is shown an example of a relationship between the actually measured values of the line widths (size) of the projection images of the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b on the wafer 50 and the pitches of the projection images when the light intensity distribution filter 5A shown in FIG. 1 is not incorporated in the exposure apparatus. When the reduced projection magnification of the projection optical system 40 is ¼, the pitches of the projection images are ¼ of the first to tenth reticle pitches PR1 to PR10. The design values of the line widths of the projection images of the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b are each 65 nm. However, as the pitch of the projection image increases due to the optical proximity effect (OPE), the design value of the line width of the projection image becomes different from the design value thereof. When the light intensity distribution filter 5A shown in FIG. 1 is incorporated in the exposure apparatus, the actually measured values of the line widths (size) of the projection images of the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b on the wafer 50, as shown in FIG. 4, are each nearly equal to 65 nm as the design value, not dependent on the pitch as shown in FIG. 14.

Where the light intensity distribution filter 5A is used, when the luminance distribution in the secondary light source plane (illumination pupil) varies, an interference wave (optical image) of the illumination light formed on the wafer 50 varies. The interference wave (optical image) of the illumination light varies depending on the size, the period and the like of the mask pattern. Therefore, the light intensity of the optical image and the contrast of the optical image vary depending on the size, the period and the like of the mask pattern. Such variations of the optical image are predictable by optical simulations. Therefore, it is possible to set the line widths of the projection images at their design values by properly designing the array of light-shielding parts of the light-shielding film located on the filter substrate 55 of the light intensity distribution filter 5A on the basis of predicted variations of the optical images, so that a light transmittance distribution of the light intensity distribution filter 5A is properly set.

When the light intensity distribution filter 5A is not incorporated in the exposure apparatus shown in FIG. 1, the line widths of the projection images by the second diffraction patterns 67a to 67f, as shown in FIG. 13, are smaller than those of the projections images by the first diffraction patterns 66a to 66f. On the other hand, when the light intensity distribution filter 5A is incorporated in the exposure apparatus shown in FIG. 1, the line widths of the projection images by the second diffraction patterns 67a to 67f are larger than those of the projections images when the light intensity distribution filter 5A is not incorporated. As a result, the line widths of the projection images by the second diffraction patterns 67a to 67f may also be each close to 65 nm of the design value, as shown in FIG. 14.

When the light intensity distribution filter 5A is not incorporated in the exposure apparatus shown in FIG. 1, the line widths of the projection images by the third diffraction patterns 68a to 68f, as shown in FIG. 13, are larger than those of the projections images by the second diffraction patterns 67a to 67f. On the other hand, when the light intensity distribution filter 5A is incorporated in the exposure apparatus shown in FIG. 1, the line widths of the projection images by the third diffraction patterns 68a to 68f are smaller than those of the projections images when the light intensity distribution filter 5A is not incorporated. As a result, the line widths of the projection images by the third diffraction patterns 68a to 68f may also be each close to 65 nm of the design value, as shown in FIG. 14.

When the light intensity distribution filter 5A is not incorporated in the exposure apparatus shown in FIG. 1, the line widths of the projection images by the fourth diffraction patterns 69a to 69e, as shown in FIG. 13, are larger than those of the projections images by the third diffraction patterns 68a to 68f. On the other hand, when the light intensity distribution filter 5A is incorporated in the exposure apparatus shown in FIG. 1, the line widths of the projection images by the fourth diffraction patterns 69a to 69e are smaller than those of the projections images when the light intensity distribution filter 5A is not incorporated. As a result, the line widths of the projection images by the fourth diffraction patterns 69a to 69e may also be each close to 65 nm of the design value, as shown in FIG. 14.

When the light intensity distribution filter 5A is not incorporated in the exposure apparatus shown in FIG. 1, the line widths of the projection images by the fifth diffraction patterns 70a to 70d, as shown in FIG. 13, are larger than those of the projections images by the fourth diffraction patterns 69a to 69e. On the other hand, when the light intensity distribution filter 5A is incorporated in the exposure apparatus shown in FIG. 1, the line widths of the projection images by the fifth diffraction patterns 70a to 70d are smaller than those of the projections images when the light intensity distribution filter 5A is not incorporated. As a result, the line widths of the projection images by the fifth diffraction patterns 70a to 70d may also be each close to 65 nm of the design value, as shown in FIG. 14.

When the light intensity distribution filter 5A is not incorporated in the exposure apparatus shown in FIG. 1, the line widths of the projection images by the sixth diffraction patterns 71a to 71d, as shown in FIG. 13, are larger than those of the projections images by the fifth diffraction patterns 70a to 70d. On the other hand, when the light intensity distribution filter 5A is incorporated in the exposure apparatus shown in FIG. 1, the line widths of the projection images by the sixth diffraction patterns 71a to 71d are smaller than those of the projections images when the light intensity distribution filter 5A is not incorporated. As a result, the line widths of the projection images by the sixth diffraction patterns 71a to 71d may also be each close to 65 nm of the design value, as shown in FIG. 14.

When the light intensity distribution filter 5A is not incorporated in the exposure apparatus shown in FIG. 1, the line widths of the projection images by the seventh diffraction patterns 72a to 72d, as shown in FIG. 13, are larger than those of the projections images by the sixth diffraction patterns 71a to 71d. On the other hand, when the light intensity distribution filter 5A is incorporated in the exposure apparatus shown in FIG. 1, the line widths of the projection images by the seventh diffraction patterns 72a to 72d are smaller than those of the projections images when the light intensity distribution filter 5A is not incorporated. As a result, the line widths of the projection images by the seventh diffraction patterns 72a to 72d may also be each close to 65 nm of the design value, as shown in FIG. 14.

When the light intensity distribution filter 5A is not incorporated in the exposure apparatus shown in FIG. 1, the line widths of the projection images by the eighth diffraction patterns 73a to 73c, as shown in FIG. 13, are larger than those of the projections images by the seventh diffraction patterns 72a to 72d. On the other hand, when the light intensity distribution filter 5A is incorporated in the exposure apparatus shown in FIG. 1, the line widths of the projection images by the eighth diffraction patterns 73a to 73c are smaller than those of the projections images when the light intensity distribution filter 5A is not incorporated. As a result, the line widths of the projection images by the eighth diffraction patterns 73a to 73c may also be each close to 65 nm of the design value, as shown in FIG. 14.

When the light intensity distribution filter 5A is not incorporated in the exposure apparatus shown in FIG. 1, the line widths of the projection images by the ninth diffraction patterns 74a to 74c, as shown in FIG. 13, are larger than those of the projections images by the eighth diffraction patterns 73a to 73c. On the other hand, when the light intensity distribution filter 5A is incorporated in the exposure apparatus shown in FIG. 1, the line widths of the projection images by the ninth diffraction patterns 74a to 74c are smaller than those of the projections images when the light intensity distribution filter 5A is not incorporated. As a result, the line widths of the projection images by the ninth diffraction patterns 74a to 74c may also be each close to 65 nm of the design value, as shown in FIG. 14.

When the light intensity distribution filter 5A is not incorporated in the exposure apparatus shown in FIG. 1, the line widths of the projection images by the tenth diffraction patterns 75a and 75b, as shown in FIG. 13, are larger than those of the projections images by the ninth diffraction patterns 74a to 74c. On the other hand, when the light intensity distribution filter 5A is incorporated in the exposure apparatus shown in FIG. 1, the line widths of the projection images by the tenth diffraction patterns 75a and 75b are smaller than those of the projections images when the light intensity distribution filter 5A is not incorporated. As a result, the line widths of the projection images by the tenth diffraction patterns 75a and 75b may also be each close to 65 nm of the design value, as shown in FIG. 14.

As described above, in the exposure apparatus of the present embodiment, since the light intensity distribution filter 5A is arranged on the plane, which plane is positioned in the illumination optical system 20 and is optically in relation of Fourier transform to the plane on which the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b are arranged, the differences in the line widths of the projection images, which are caused due to the first to tenth reticle pitches PR1 to PR10, can be corrected. In the present embodiment, as shown in FIG. 13, the error correction for correcting such an error that the line width of the projection image has a tendency to increase with increase in the pitches of the projection images is exemplarily presented. On the other hand, in the case where the line width of the projection image has a tendency to increase with decrease of the pitch of the projection image, the differences in the line widths of the projection images can be corrected by arranging a light intensity distribution filter 5B on the plane, which plane is positioned in the illumination optical system 20 and is optically in relation of Fourier transform to the mask pattern of the photomask 30. The light intensity distribution filter 5B has a light transmittance distribution configured such that the light transmittance is the largest at the center C of the aperture 57 and becomes small toward the periphery of the aperture 57 as shown in FIGS. 15A and 15B. In the light intensity distribution filter 5B, the pitches of light-shielding parts (not shown) arrayed in the aperture 57 become small from the center C of the aperture 57 toward the periphery thereof, as reverse to the pitch array of the light intensity distribution filter 5A shown in FIG. 5. Therefore, the transmittance, as shown in FIG. 15B, is the largest at the center C of the aperture and becomes smaller toward the periphery thereof as reverse to the light intensity distribution filter 5A shown in FIG. 5. In other words, the light intensity distribution filter 5B has a transmittance distribution expressed by a quadratic curve, which ascends toward the center C when viewed in the radial direction.

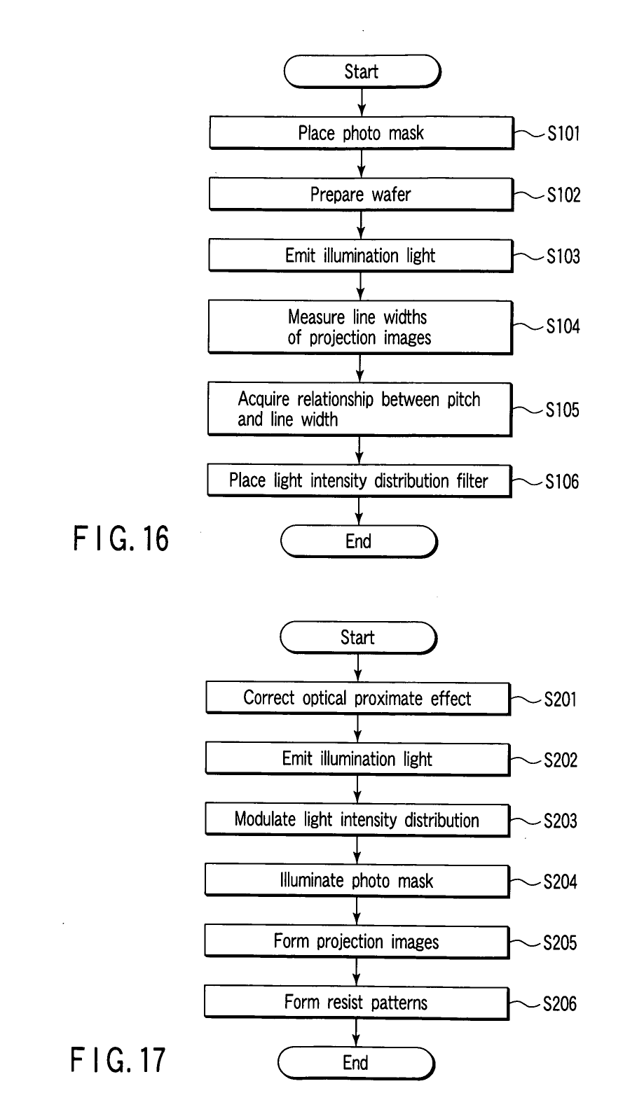

An optical proximity correction (OPC) method according to the embodiment of the present invention will be described with reference to a flowchart shown in FIG. 16.

(a) In step S101, a photomask 30 shown in FIG. 4 is placed on the mask stage 31 of the exposure apparatus shown in FIG. 1. In step S102, a resist film is formed on the wafer 50 by spin coating process, and the resist-coated wafer is placed on the wafer stage 51. In step S103, in a state that the light intensity distribution filter 5A is not placed, the light source 10 is driven to emit illumination light and to form on the wafer 50 the projection images of the first diffraction patterns 66a to 66f, second diffraction patterns 67a to 67f, third diffraction patterns 68a to 68f, fourth diffraction patterns 69a to 69e, fifth diffraction patterns 70a to 70d, sixth diffraction patterns 71a to 71d, seventh diffraction patterns 72a to 72d, eighth diffraction patterns 73a to 73c, ninth diffraction patterns 74a to 74c, and the tenth diffraction patterns 75a and 75b, which are formed on the photomask 30.

(b) In step S104, the first line widths, i.e., the line widths of the projection images of the first diffraction patterns 66a to 66f are measured by using a CCD camera, for example. Also, the following line widths are measured: the second, third and fourth line widths, i.e., the line widths of the projection images of the second diffraction patterns 67a to 67f, the third diffraction patterns 68a to 68f, and the fourth diffraction patterns 69a to 69e. The following line widths are also measured: the fifth, sixth and seventh line widths, i.e., the line widths of the projection images of the fifth diffraction patterns 70a to 70d, sixth diffraction patterns 71a to 71d, and seventh diffraction patterns 72a to 72d. Further, the following line widths are also measured: the eighth, ninth and tenth line widths, i.e., the line widths of the projection images of the eighth diffraction patterns 73a to 73c, ninth diffraction patterns 74a to 74c, and the tenth diffraction patterns 75a and 75b.

(c) In step S105, a relationship between the pitches of the projection images and the first to tenth line widths is acquired. In the example shown in FIG. 13, as the pitches of the projection images increase, the line widths of the projection images has a tendency to increase. In this case, in step S106, the light intensity distribution filter SA shown in FIGS. 5 to 10, in which the transmittance increases from the center C through which the optical axis passes toward the periphery as viewed in the direction perpendicular to the optical axis, is placed on a plane which is optically in relation of Fourier transform to the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b, and the optical proximity correction (OPC) process of the embodiment ends.

(d) When the smaller the pitches of the projection images are, the larger the line widths of the projection images are in step S105, the light intensity distribution filter 5B shown in FIG. 15A, in which the transmittance decreases from the center C through which the optical axis passes to the periphery as viewed in the direction perpendicular to the optical axis, is placed on a plane which is optically in relation of Fourier transform to the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b, and the optical proximity correction (OPC) process of the embodiment ends.

By projecting the images of the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b onto the wafer 50 by using the exposure apparatus having undergone the optical proximity correction (OPC) process as described above, the projection images can be formed which are not dependent on the first to tenth reticle pitches PR1 to PR10 and of which the line widths (size) have been corrected to be the design values. In an alternative, the relationship between the pitches of the projection images and the line widths of the projection images may be obtained in such a way that the projection images are formed in step S103, and then the resist film on the wafer 50 is developed to form resist patterns, and the line widths of the resist patterns are observed by an atomic force microscope (AFM) or scanning electron microscope (SEM). When the resist film is the positive photoresist film, the portions of the resist film in which the projection images are formed are dissolved by the development process. Accordingly, it is only necessary to measure the line widths of the openings of the resist patterns formed by the developing process. When the resist film is the negative photoresist film, the portions in which no projection images are formed are dissolved by the development process. Accordingly, it is only necessary to measure the line widths of the resist patterns formed by the developing process.

A method of manufacturing a semiconductor device by using the exposure apparatus according to the embodiment will be described with reference to a flowchart shown in FIG. 17.

(a) In step S201, the optical proximity correction (OPC) process described referring to FIG. 16 is carried out. In step S202 of FIG. 17, a resist film is formed on the wafer 50 by spin coating, and the resist-coated wafer is placed on the wafer stage 51. The light source 10 shown in FIG. 1 is driven to emit illumination light. The illumination light passes through the lens system 21 and the fly-eye lens 22, and the diameter of the cross section of the bundle of the illumination light is defined by the lighting stop 23.

(b) In step S203, the light intensity distribution filter 5A varies a light intensity distribution of the illumination light in the cross section of the bundle of the illumination light. In step S204, the illumination light passes through the lens 24, the exposure area stop 25 and the lenses 26 and 27 and reaches the photomask 30 (FIG. 1). The illumination light is diffracted by the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b shown in FIG. 4, and forms Fourier images of the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b in the pupil plane in the projection optical system 40.

(c) In step S205, the illumination light passes through the projection optical system 40 shown in FIG. 1 to form the projection images of the first to tenth diffraction patterns 66a to 66f, 67a to 67f, 68a to 68f, 69a to 69e, 70a to 70d, 71a to 71d, 72a to 72d, 73a to 73c, 74a to 74c, and 75a and 75b on the resist film on the wafer 50. In step S206, the resist film on the wafer 50 is subjected to developing process to form resist patterns on the wafer 50. Then, impurity ions are injected into the wafer 50, and a known fabricating process is carried out to complete the manufacture of a semiconductor device of the embodiment.

The method of manufacturing semiconductor devices of the embodiment described above is capable of suppressing the differences in the line widths of the resist patterns, which is due to the optical proximity effect (OPE). Therefore, the semiconductor device can be fabricated with high precision.

Generally, a mask pattern including a plurality of diffraction patterns, which are different in size and period, is formed on the photomask 30. In the projection exposure method in which the image of the mask pattern is projected onto a resist film on the wafer 50, a dimensional error of the mask pattern possibly causes an error in the projection image on the resist film. Therefore, when dimensional errors exist in the mask pattern, the resist patterns formed by developing the resist film have also dimensional errors. Also, when the optical proximity effect (OPE) and the process proximity effect (PPE) occur, it is not always possible to form the resist patterns of the design size even if the size of the diffraction patterns is obtained by dividing the design size of the resist patterns by the projection magnification of the projection optical system 40.

To cope with this, the following process has been performed before the photomask 30 is fabricated. The influence of the optical proximity effect (OPE) and the process proximity effect (PPE) upon the dimensional errors of the resist patterns is predicted by a simulation, on the basis of the illumination optical system 20 and the projection optical system 40 of the exposure apparatus, resist film material, post exposure baking (PEB) condition, and development condition, and then the optical proximity correction (OPC) for correcting the size and the configuration of the mask pattern and the process proximity correction (PPC) are carried out. In the case where any problem exists in fabricating process of the photomask 30 and the mask pattern has a dimensional error, the resist patterns inevitably suffer from the dimensional error even if the optical proximity correction (OPC) and the process proximity correction (PPC) are carried out. It is difficult to incorporate all the environmental factors, including the exposure process, the post exposure baking (PEB) following the exposure and the developing process into the simulation as parameters. Therefore, there are cases in which the optical proximity correction (OPC) and the process proximity correction (PPC) are inappropriately carried out. Even in the case where no dimensional error is contained in the mask pattern and the optical proximity correction (OPC) is normally carried out, when the light source 10, the illumination optical system 20 and the projection optical system 40 of the exposure apparatus are aged, there is the possibility that the optical proximity effect (OPE) also varies and the optical proximity correction (OPC) becomes invalid. Similarly, even in the case where the process proximity correction (PPC) involves no problem, when the resist film, the heating device for the post exposure baking (PEB), the developing equipment, and the like are aged, there is the possibility that the process proximity effect (PPE) varies and the process proximity correction (PPC) becomes invalid.

In such a case, if the resist film is subjected to the exposure process by using the photomask 30 manufactured, desired resist patterns are not formed. If the total amount of the exposure light is adjusted so that a projection image of a specific diffraction pattern has a desired size, the size of the projection image of another diffraction pattern having different size and period is sometimes off the desired value. Generally, when an error occurs in the optical proximity correction (OPC), there is little chance of quickly finding the cause of the error. Accordingly, it is difficult to remove the problem causing the inappropriate optical proximity effect (OPE). In such a case, the conventional approach is to re-fabricate the photomask 30 to which the correct optical proximity correction (OPC) is applied. However, much cost and time loss are unavoidable to fabricate the photomask 30. In connection with this, it is noted that the semiconductor device fabricating method of the embodiment is capable of correcting the line widths of the projection images of the diffraction patterns by setting the light intensity distribution filter 5A to the exposure apparatus.

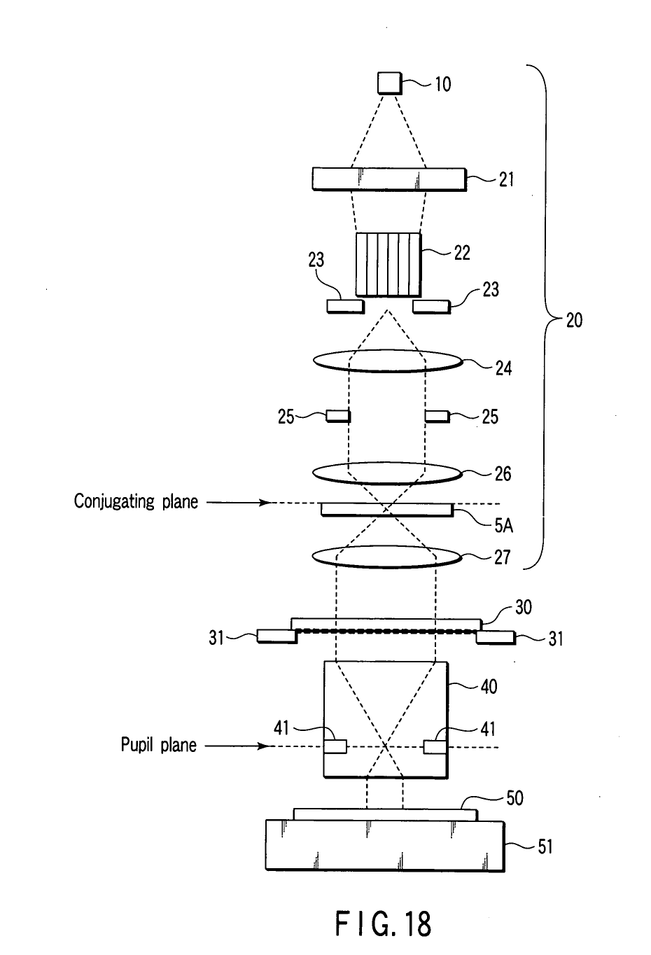

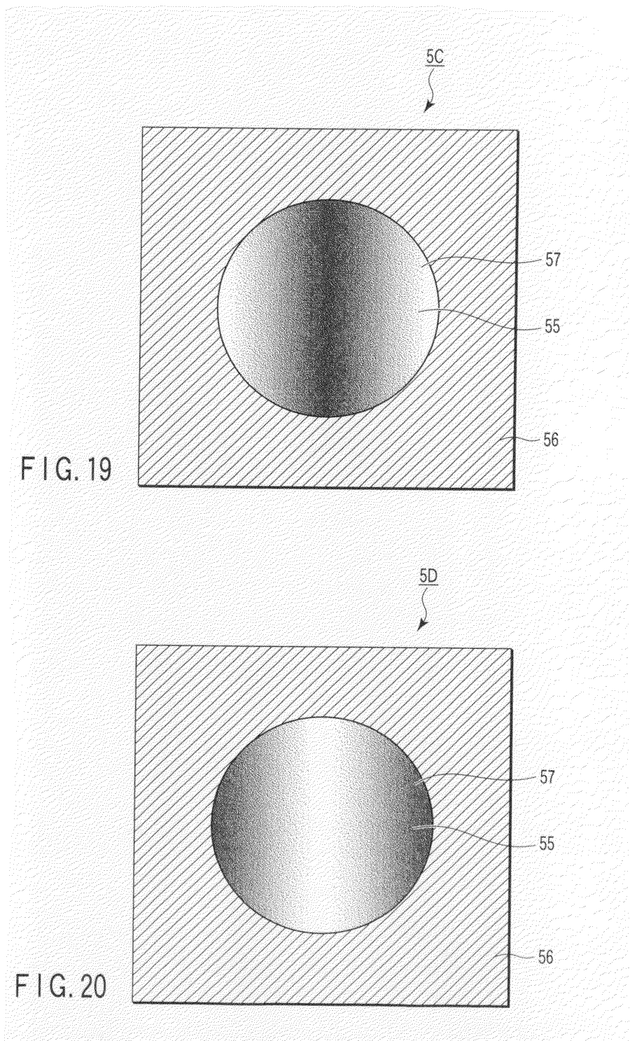

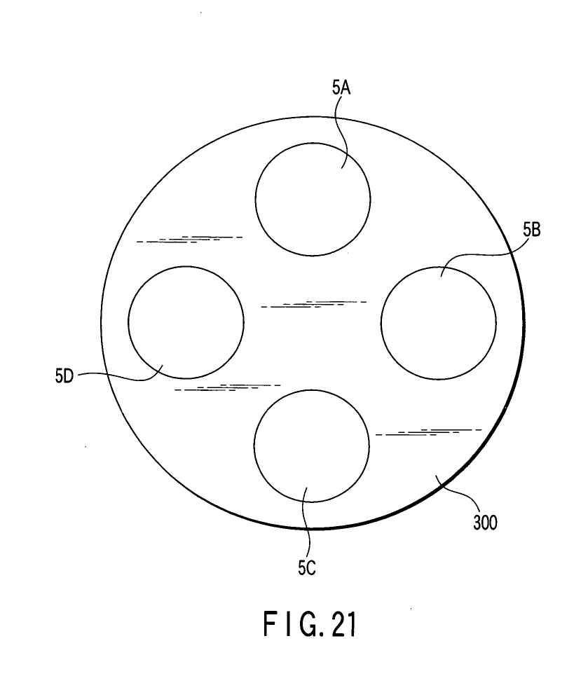

It should be understood that the present invention is not limited to the above-mentioned embodiments. In FIG. 1, the light intensity distribution filter 5A is located in contact with the lighting stop 23. Instead, the light intensity distribution filter 5A may be placed on the plane on which the focal point of the lens 26 is set, as shown in FIG. 18, since the focal point position of the lens 26 is a position optically in relation of Fourier transformation with regard to the plurality of mask patterns of the photomask 30. Also, in the embodiment described above, the light intensity distribution filter 5A in which the transmittance coaxially varies as shown in FIG. 11A is used for the light intensity distribution filter. However, in the case where the mask pattern of the photomask 30 is longitudinally unidirectional, a light intensity distribution filter 5C or a light intensity distribution filter 5D may be used instead. In the light intensity distribution filter 5C, the transmittance increases from the center of the aperture 57 to the periphery only in one direction, as shown in FIG. 19. In the light intensity distribution filter 5D, the light transmittance decreases from the center of the aperture 57 to the periphery only in one direction, as shown in FIG. 20. Further, in the previous embodiment, the light-shielding parts 60a to 60c and 60o to 60q shown FIGS. 7 to 10 are coaxially arrayed on the filter substrate 55 such that the filter pitches increase from the center C of the aperture 57 to the periphery. However, in an alternative, the filter pitches are fixed and the sizes of the light-shielding parts 60a to 60c and 60o to 60q are varied from the center C to the periphery. In a modification, as shown in FIG. 21, a revolver 300 which holds the light intensity distribution filters 5A to 5D may be placed on a plane which is optically in relation of Fourier transform to the plurality of mask patterns of the photomask 30 of the exposure apparatus shown in FIG. 1. In this case, by rotating the revolver 300 according to the line widths of the projection images of the plurality of mask patterns, one of the light intensity distribution filters 5A to 5D is selectively placed orthogonally to the optical axis of the illumination optical system 20, whereby the correction is made to arrange the line widths of the plurality of mask patterns as intended. In another modification, an opening not holding any of the light intensity distribution filters 5A to 5D is formed in the revolver 300. When no optical proximity effect (OPE) occurs, the opening may be set to be orthogonal to the optical axis of the illumination optical system 20.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An exposure apparatus comprising:
an illumination optical system including a light source which emits illumination light;
a mask stage which holds a photomask having a mask pattern thereon to be illuminated with the illumination light; and
a light intensity distribution filter arranged on a plane, which plane is positioned in the illumination optical system and is optically in relation of Fourier transform to the mask pattern, the light intensity distribution filter configured to vary a light intensity distribution of the illumination light in a cross section of a bundle of the illumination light.

2. An exposure apparatus according to claim 1, wherein the light intensity distribution filter includes a filter substrate transparent to the illumination light and a plurality of light-shielding parts opaque to the illumination light and arrayed on the filter substrate at pitches varying in a direction orthogonal to an optical axis of the illumination optical system.

3. An exposure apparatus according to claim 1, wherein the plane optically in relation of Fourier transform to the mask pattern is a plane on which a lighting stop in the illumination optical system contacts, and the light intensity distribution filter is located on the plane on which the lighting stop contacts.

4. An exposure apparatus according to claim 1, wherein the plane optically in relation of Fourier transform to the mask pattern is a plane on which a focal point of a condensing lens for condensing the illumination light having passed through a lighting stop for an exposure area in the illumination optical system is set, and the light intensity distribution filter is located on the plane on which the focal point of the condensing lens is set.

5. An exposure apparatus according to claim 2, wherein the plurality of light-shielding parts are arrayed such that a light transmittance of the light intensity distribution filter to the illumination light coaxially varies.

6. An exposure apparatus according to claim 2, wherein the plurality of light-shielding parts are arrayed such that the pitches of the light-shielding parts coaxially vary in the direction orthogonal to the optical axis of the illumination optical system.

7. An exposure apparatus according to claim 6, wherein the plurality of light-shielding parts are arrayed such that a light transmittance of the light intensity distribution filter to the illumination light increases with increase in a distance from the optical axis in the direction orthogonal to the illumination light.

8. An exposure apparatus according to claim 7, wherein the plurality of light-shielding parts are arrayed such that the pitches of the light-shielding parts coaxially increase with increase in a distance from the optical axis of the illumination optical system in the direction orthogonal to the optical axis of the illumination optical system.

9. An exposure apparatus according to claim 6, wherein the plurality of light-shielding parts are arrayed such that the light transmittance of the light intensity distribution filter to the illumination light decreases with increase in a distance from the optical axis in the direction orthogonal to the illumination light.

10. An exposure apparatus according to claim 9, wherein the plurality of light-shielding parts are arrayed such that the pitches of the light-shielding parts coaxially decrease with increase in a distance from the optical axis of the illumination optical system in the direction orthogonal to the optical axis of the illumination optical system.

11. An exposure apparatus according to claim 1, wherein the plurality of light-shielding parts are arrayed such that a light transmittance of the light intensity distribution filter to the illumination light increases only in one direction in a direction orthogonal to an optical axis of the illumination light.

12. An exposure apparatus according to claim 1, wherein the plurality of light-shielding parts are arrayed such that a light transmittance of the light intensity distribution filter to the illumination light decreases only in one direction in a direction orthogonal to an optical axis of the illumination light.

13. An exposure apparatus according to claim 2, wherein the pitches of the plurality of light-shielding parts of the light intensity distribution filter have sizes so that the illumination light is prevented from being diffracted at the light-shielding parts.

14. An exposure apparatus according to claim 13, wherein the pitches of the plurality of light-shielding parts are each 10 times or higher than a wavelength of the illumination light.

15. An exposure apparatus according to claim 13, wherein the pitches of the plurality of light-shielding parts are each shorter than a wavelength of the illumination light.

16. An exposure method comprising:
emitting illumination light from a light source of a illumination optical system;
varying a light intensity distribution of the illumination light in a cross section of a bundle of the illumination light by using a light intensity distribution filter placed in an optical path of the illumination light in the illumination optical system; and
illuminating a mask pattern positioned on a plane optically in relation of Fourier transform to the light intensity distribution filter with the illumination light.

17. An exposure method according to claim 16, wherein a light intensity distribution filter, in which the light transmittance increases or decreases with increase in a distance from an optical axis in the direction orthogonal to the optical axis of the illumination light, is used for the light intensity distribution filter.

18. An exposure method according to claim 16, wherein a light intensity distribution filter, in which the light transmittance increases or decreases only in the same direction in the direction orthogonal to the optical axis of the illumination light, is used for the light intensity distribution filter.

19. An optical proximity correction method comprising:
illuminating a mask pattern including a plurality of diffraction patterns having different periods with illumination light generated from a light source;
measuring sizes of projection images of the plurality of diffraction patterns formed by illumination of the illumination light; and
varying, when the sizes of the projection images measured are each different from target values, a light intensity distribution in a cross section of a bundle of the illumination light on a plane which is between the mask pattern and the light source and is optically in relation of Fourier transform to the mask pattern, to correct the sizes of the projection images to be close to the target values.

20. An optical proximity correction method according to claim 19, wherein the sizes of the projection images are corrected to be close to the target values by placing a light intensity distribution filter, in which a light transmittance increases with increase in a distance from an optical axis in a direction orthogonal to the illumination light, on the plane optically in relation of Fourier transform to the mask pattern.

21. An optical proximity correction method according to claim 19, wherein the sizes of the projection images are corrected to be close to the target values by placing a light intensity distribution filter, in which a light transmittance decreases with increase in a distance from an optical axis in a direction orthogonal to the illumination light, on the plane optically in relation of Fourier transform to the mask pattern.
